(19) United States
(12) Patent Application Publication
(10) Pub. No.: US 2017/0077050 A1
(43) Pub. Date: Mar. 16, 2017

(54) TECHNIQUES FOR FORMING INTEGRATED PASSIVE DEVICES

(71) Applicant: INTEL CORPORATION, Santa Clara, CA (US)

(72) Inventors: RANY T. ELSAYED, Rancho Cordova, CA (US); NITI GOEL, Portland, OR (US); SILVIO E. BOU-GHAZALE, Hillsboro, OR (US); ANSHUMALI ROY, Portland, OR (US); JOSEPH C. YIP, Portland, OR (US)

(73) Assignee: INTEL CORPORATION, Santa Clara, CA (US)

(21) Appl. No.: 15/125,442

(22) PCT Filed: Jun. 25, 2014
(86) PCT No.: PCT/US2014/044101

§ 371 Date: Sep. 12, 2016

(51) Int. Cl. H01L 23/66; H01L 49/02

(52) U.S. Cl. CPC H01L 23/66; H01L 28/10; H01L 28/60; H01L 2223/6672

(57) ABSTRACT

Techniques are disclosed for forming integrated passive devices, such as inductors and capacitors, using next-generation lithography (NGL) processes, such as electron-beam direct write (EBDW) and extreme ultraviolet lithography (EUVL). The techniques can be used to form various different integrated passive devices, such as inductors (e.g., spiral inductors) and capacitors (e.g., metal finger capacitors), having higher density, precision, and quality factor (Q) values than if such devices were formed using 193 nm photolithography. The high Q and dense passive devices formed can be used in radio frequency (RF) and analog circuits to boost the performance of such circuits. The increased precision may be realized based on an improvement in, for example, line edge roughness (LER), achievable resolution/critical dimensions, sharpness of corners, and/or density of the formed structures.

### BACKGROUND

In any circuit design, the characteristics of integrated passive devices significantly impact the overall circuit performance. Unlike active devices, passive devices do not require an external source of energy to function. Instead, passive devices impede current flow through external resistance, store charge through capacitance, or produce a voltage in response to changes in current through inductance, for example. The quality factor (Q) of inductors, capacitors, and inductor-capacitor circuits (LC circuits) is often used to give an indication of performance of the components in, for example, radio frequency (RF) and analog circuits. Q indicates energy loss relative to the amount of energy stored within the system. Thus, the higher the Q, the lower the rate of energy loss.

### BRIEF DESCRIPTION OF THE DRAWINGS

FIGS. 1A and 1B illustrate example double patterning photolithography masks used to form the structure shown in FIG. 1C.

FIG. 1C illustrates a structure formed using 193 nm photolithography.

FIG. 2 illustrates a single resist feature line having two edges, a left edge and a right edge, to help illustrate the concept of line edge roughness (LER).

FIG. 3A illustrates an example inductor formed on a substrate, in accordance with an embodiment of the present disclosure.

FIG. 3B illustrates an example capacitor formed on a substrate, in accordance with an embodiment of the present disclosure.

FIG. 4 illustrates a computing system implemented with integrated circuit structures or devices, such as integrated passive devices (e.g., inductors and/or capacitors), formed using the techniques disclosed herein, in accordance with an example embodiment.

### DETAILED DESCRIPTION

Techniques are disclosed for forming integrated passive devices, such as inductors and capacitors, using next-generation lithography (NGL) processes, such as electron-beam direct write (EBDW) and extreme ultraviolet lithography (EUVL). The techniques can be used to form various different integrated passive devices, such as inductors (e.g., spiral inductors) and capacitors (e.g., metal finger capacitors), having higher density, precision, and quality factor (Q) values than if such devices were formed using 193 nm photolithography. The high Q and dense passive devices formed can be used in radio frequency (RF) and analog circuits to boost the performance of such circuits. The increased precision may be realized based on an improvement in, for example, line edge roughness (LER), achievable resolution/critical dimensions, sharpness of corners, and/or density of the formed structures. Numerous configurations and variations will be apparent in light of this disclosure.

General Overview

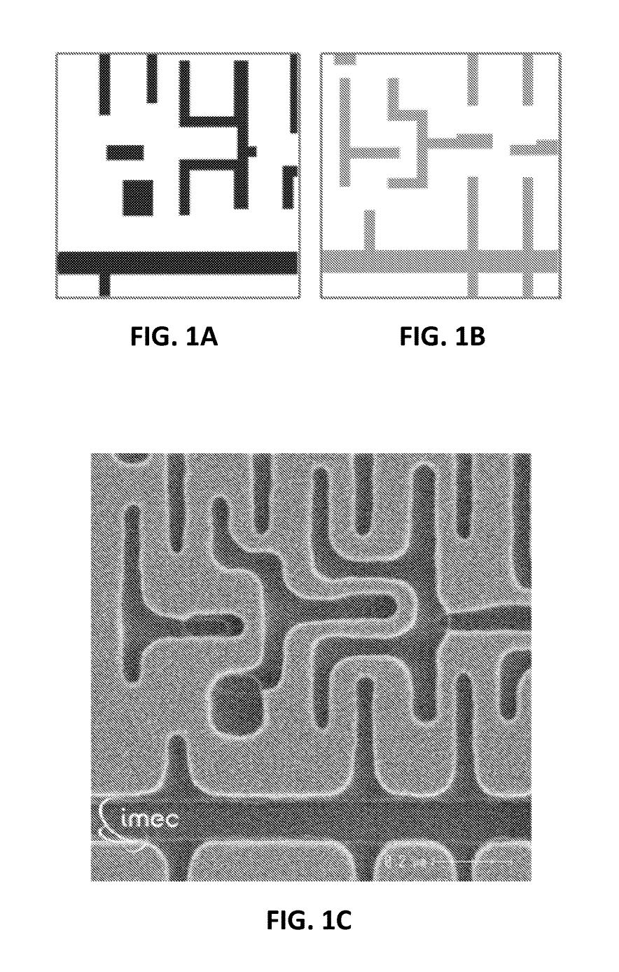

As previously described, the quality factor (Q) of inductors, capacitors, and inductor-capacitor circuits (LC circuits) is often used to give an indication of performance of the components in, for example, radio frequency (RF) and analog circuits. Generally, high Q inductors, capacitors, and LC circuits are desired. This is particularly the case for high frequency circuits, which require high Q inductors and capacitors. Q can be improved in a number of ways, including improving density, precision, and line sharpness of the component involved. Conventionally, 193 nm photolithography has been used to form integrated inductors and capacitors for RF and analog circuits. However, 193 nm photolithography has numerous limitations, particularly for sub-100 nm resolution applications. Such limitations include requiring multiple lithography processes, requiring multiple masks, requiring additional materials, lack of precision, lack of capability to form dense components, lack of capability to form sharp angles, and lack of consistency throughout formed structures, just to name a few limitations. For example, FIGS. 1A and 1B illustrate example double patterning photolithography masks used to form the structure shown in FIG. 1C. Comparing the mask patterns in FIGS. 1A and 1B to the resulting structure in FIG. 1C, it can be seen that the straightness of the lines and sharpness of the 90 degree angles in the mask patterns were not preserved in the resulting structure. In other words, the resulting structure in FIG. 1C, which was formed using conventional 193 nm photolithography, includes undesired line roughness and corner rounding. This results in an inability to create devices with high precision, accuracy, and density, especially for sub-100 nm applications. Such restrictions reduce the Q value of the device formed, because the Q value of a device decreases as the precision, accuracy, and density of the device decreases.

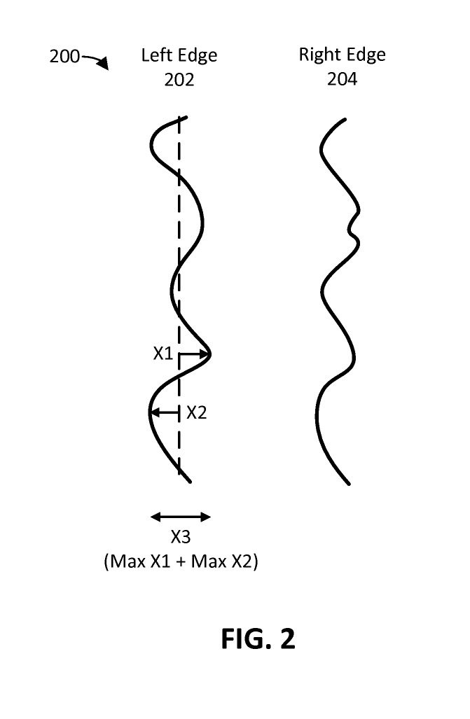

When variations in the width of a resist feature line occur over the length of the line, the variation is called line width roughness (LWR). When examining these variations along just one edge of a resist feature line, it is called line edge roughness (LER). LER becomes particularly important for feature sizes on the order of 100 nm or less, and can become a significant source of problems. LER is typically characterized as 3 standard deviations of a line edge from a straight line. For example, FIG. 2 illustrates a single resist feature line 200 having two edges, a left edge 202 and a right edge 204. As can be seen in FIG. 2, the left edge 202 is not perfectly straight and has deviations from the straight dotted line. These deviations are shown as X1 for deviations to the right of the straight line and X2 for deviations to the left of the straight line. The total maximum deviation may also be quantified as X3, or the combination of the maximum X1 deviation and the maximum X2 deviation, for a given section of the line edge. 193 nm photolithography typically has LER values of 4 nm or greater, which is a limiting factor in achieving high levels of precision and accuracy in integrated passive devices, such as inductors and capacitors used in high frequency circuits.

Thus, and in accordance with one or more embodiments of the present disclosure, techniques are disclosed for forming integrated passive devices using next-generation lithography (NGL) processes, such as electron-beam direct write (EBDW) and extreme ultraviolet lithography (EUVL). As will be apparent in light of the present disclosure, other NGL processes may be used to form the integrated passive devices described herein, such as nanoimprint lithography; therefore, the present disclosure is not intended to be limited to any NGL process unless otherwise indicated. The techniques can be used to form various different integrated passive devices, such as inductors (e.g., spiral inductors) and capacitors (e.g., metal finger capacitors (MFCs)), having higher density, precision, and Q values than if such devices were formed using 193 nm photolithography. This results in increased performance and yield of the integrated passive devices, which is beneficial for RF, LC, and analog circuits, and is especially important for high frequency circuits (such as high 3 db cut-off frequency structures) which require components with high precision and high Q values.

In some embodiments, forming inductors and capacitors with the techniques described herein (e.g., using EBDW or EUVL) can result in the structures having improved LER, such as LER below 4 nm or below 2 nm, for example. Further, the techniques described herein allow for precise resist features to be formed, even when forming resist features having critical dimensions of 30 nm or less (or even 10 nm or less). This increased precision allows the inductors and capacitors to be formed with higher density and thereby increases the Q value of the resulting structures. The techniques described herein may also allow for increased accuracy and/or critical dimension uniformity (CDU). Parasitic resistance in the passive devices is also minimized by the ability to form the passive devices with sharper corners (e.g., as compared to what can be achieved using 193 nm photolithography). In addition, these improved results are achieved with one lithography process and one or no mask (depending upon the specific NGL process used), which is another advantage over 193 nm photolithography, because 193 nm photolithography requires multiple lithography processes and multiple masks to, for example, reach sub-100 nm resolution.

Upon analysis (e.g., using scanning/transmission electron microscopy (SEM/TEM) and/or composition mapping), a structure or device configured in accordance with one or more embodiments will effectively show an integrated passive device having increased precision, density, and/or Q values compared to a structure or device formed using conventional 193 nm photolithography. For example, devices formed using the techniques as variously described herein may include precise resist features, such as straight line portions, having LER values of 4 nm or less, 2 nm or less, or some other suitable high precision cap. Devices formed using the techniques as variously described herein may also include precise resist features having critical dimensions below 100 nm, 30 nm, 10 nm, or some other suitable cap. In addition, integrated passive devices formed using the techniques described herein can achieve higher Q values than if such devices were formed using 193 nm photolithography, and the Q value can be measured to determine if such as structure was formed using the techniques described herein. Some embodiments may result in up to a 2×, 5×, or 10× improvement in Q value, or an even greater improvement. Numerous configurations and variations will be apparent in light of this disclosure.

Architecture and Methodology

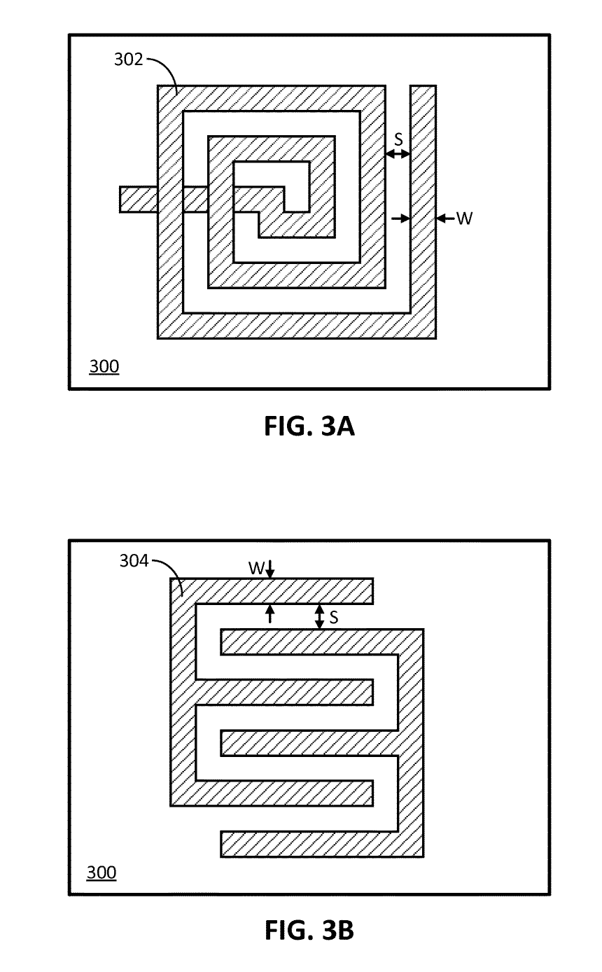

FIG. 3A illustrates an example inductor 302 formed on a substrate 300, in accordance with an embodiment of the present disclosure. As can be seen in FIG. 3A, inductor 302 is an integrated spiral inductor formed of an electrically conductive coil having multiple connected line portions. FIG. 3B illustrates an example capacitor 304 formed on a substrate 300, in accordance with an embodiment of the present disclosure. As can be seen in FIG. 3B, capacitor 304 is a (metal) finger capacitor formed of two sets of electrically conductive fingers that are intertwined with each other, where each set of fingers has multiple connected line portions. Inductor 302 and capacitor 304 are provided to illustrate the techniques described herein and are also provided as two example resulting structures formed using the techniques described herein. However, inductor 302 and capacitor 304 are not intended to limit the present disclosure. The techniques, as variously described herein, can include forming an electrically conductive material (e.g., a metal containing material) on a substrate (e.g., a semiconductor substrate), forming a resist on the electrically conductive layer, and then patterning the resist using a next-generation lithography (NGL) process. The NGL process may be electron-beam lithography or electron-beam direct write (EBDW), extreme ultraviolet lithography (EUVL), or another suitable process as will be apparent in light of this disclosure.

The substrate 300 may be any suitable substrate, such as a semiconductor substrate or an insulator substrate. For example, substrate 300 may comprise silicon (Si), germanium (Ge), silicon germanium (SiGe), one or more III-V materials, glass, an oxide material (e.g., silicon dioxide), a nitride material (e.g., silicon nitride), and/or any other suitable semiconductor or insulator material. In some embodiments, substrate 300 may be configured as a bulk substrate, a semiconductor-on-insulator (XOI, where X is a semiconductor material such as Si, Ge, or SiGe), or a multi-layered structure. Other suitable substrate materials and/or configurations will depend on a given target application or end use, and will be apparent in light of this disclosure.

The electrically conductive layer (e.g., the layer from which inductor 302 and capacitor 304 were formed) may comprise any suitable material, such as one or more metals or metal alloys. For example, the electrically conductive material may comprise copper (Cu), aluminum (Al), gold (Au), silver (Ag), and/or any other electrically conductive material. In some embodiments, the electrically conductive material may comprise a magnetic material, such as one or more ferromagnetic materials (e.g., cobalt (Co), nickel (Ni), ferrite, etc.). The electrically conductive layer may be formed on substrate 300 using any suitable technique, such as a physical vapor deposition (PVD) process (such as sputter deposition), a chemical vapor deposition (CVD) process, an atomic layer deposition (ALD) process, a molecular beam epitaxy (MBE) process, and/or any other suitable growth or deposition process. Other suitable electrically conductive materials and/or configurations will depend on a given target application or end use, and will be apparent in light of this disclosure.

The resist (not shown) used to help form inductor 302 and capacitor 304 may comprise any suitable material, including, but not limited to, an organic photoresist material (e.g., poly(methyl methacrylate), poly(dimethyl glutarimide), phenol formaldehyde resin, US-8, or other polymer), an inorganic photoresist material (e.g., chalcogenide), a molecular photoresist material (e.g., truxene), a high resolution resist (e.g., hydrogen silsesquioxane (HSQ)), a hybrid of the aforementioned, and/or any other material suitable for use as a resist on the electrically conductive material layer. The resist material may be deposited using any suitable process, including, but not limited to, spin coating. The resist materials and thicknesses may be selected, in some instances, based on the lithography process being used to pattern the resist. For example, when using electron-beam lithography or EBDW, the resist may be an electron sensitive film capable of having its solubility changed by an electron beam. However, in some instances, a suitable photoresist may be used for the electron-beam exposure. Other suitable resist materials and/or configurations will depend on a given target application or end use, and will be apparent in light of this disclosure.

After the resist is deposited on the electrically conductive layer, it can be patterned using one or more lithography processes. In some embodiments, the resist is patterned using electron-beam lithography or EBDW, EUVL, nanoimprint lithography, or some other suitable NGL process. In some embodiments, the lithography process may require one or no masks and may also require only one lithography process. For example, EBDW is a maskless lithography process where one or more focused beams of electrons can be used to pattern the resist in a single lithography process. In another example, EUVL uses an extreme ultraviolet wavelength (e.g., 13.5 nm) and a single mask to pattern the resist in a single lithography process. In some such embodiments, the lithography process may be able to achieve high precision resist features even with the use of one or no masks, including being able to achieve sub-100 nm, sub-50 nm, sub-30 nm, or sub-10 nm resolution, for example. In other words, the lithography process used to form inductor 302 and capacitor 304, may be able to achieve resist features having sub-100 nm, sub-50 nm, sub-30 nm, or sub-10 nm critical dimensions, as will be discussed in more detail herein.

After the lithography process has been performed, subsequent resist processing may be required to properly pattern the resist. For example, such processing may include using an appropriate solvent to remove the areas that were exposed during the lithography processing or other suitable processing. After the resist has been properly patterned, the underlying electrically conductive layer can be etched to transfer the pattern to that layer. Any suitable wet or dry etch may be used, and in some embodiments, the etchant and/or etch process may be dictated by the resist properties (e.g., the material and/or thickness of the resist) and/or the properties of the electrically conductive layer (e.g., the material and/or thickness of the layer). Once the resist pattern is transferred, the resist may be removed using any suitable process, such as a resist stripping or planarization process. Inductor 302 and capacitor 304 show two such resulting structures formed after the resist has been removed to reveal the underlying patterned electrically conductive layer.

As can be seen in FIGS. 3A and 3B, inductor 302 and capacitor 304 each have a plurality of line portions, with the line portions each having widths W and separated from adjacent and substantially parallel line portions by spaces S. As previously described, using NGL process such as EBDW and EUVL allows for better resolutions to be achieved (e.g., as compared to using 193 nm photolithography). In some embodiments, the better resolutions result in being able to achieve sub-100 nm, sub-50 nm, sub-30 nm, or sub-10 nm dimensions for S and W. Although inductor 302 and capacitor 304 have consistent lines and spaces (having dimensions W and S, respectively) throughout the entire structure, the present disclosure is not intended to be so limited. The widths and spaces of the resist features may vary within a single inductor or capacitor, for example. However, in some instances, it may be beneficial to have uniform and consistent features for spiral inductors and (metal) finger capacitors, and the techniques described herein can achieve higher critical dimension uniformity (CDU) for the passive devices than if they were formed using conventional 193 nm lithography.

The use of NGL processes, such as EBDW and EUVL to form inductor 302 and capacitor 304 also provides the benefit of being able to achieved improved line edge roughness (LER) values (e.g., as compared to using conventional 193 nm lithography). For example, the NGL processes may be able to achieve LER of 4 nm or less, 3 nm or less, 2 nm or less, 1 nm or less, or some other suitable cap for LER values of the lines in the structures as will be apparent in light of this disclosure. Further, the maximum edge deviation (e.g., X3 in FIG. 2) for a given straight line portion of inductor 302 or capacitor 304 may be 10 nm, 8 nm, 5 nm, 2 nm, 1 nm, or some other suitable maximum amount as will be apparent in light of this disclosure. In this manner, high precision passive devices can be formed having high Q values, which is particularly important for high frequency circuits. In addition, the techniques described herein can achieve various angles between any two connecting line portions of an inductor or capacitor, in some embodiments, such as angles between 60 and 140 degrees. In some embodiments, the angles achieved may all be within 5 degrees of 90 degrees, such as is the case in the example structures shown in FIGS. 3A and 3B (where all angles are exactly 90 degrees). Further, the corners between any two line portions is sharper (or less round/rounded) than can be achieved using conventional 193 nm photolithography (e.g., compare the structure formed in FIG. 1C and the structures in FIGS. 3A and 3B).

As previously described, inductor 302 and capacitor 304 are provided as two example resulting structures formed using the techniques described herein and are not intended to limit the present disclosure. For example, although inductor 302 is shown having a substantially square shape, the techniques variously described herein can be used to form spiral inductors having rectangular, pentagonal, hexagonal, or octagonal shapes, just to name a few other examples. In addition, although inductor 302 is shown having only a couple of turns, the inductors formed using the techniques variously described herein can have any number of turns. In some embodiments, the inductors can have a higher number of turns for a given area (and thus, improved density) as compared to what would be capable if the inductors were formed using conventional 193 nm photolithography, thereby resulting in inductors having improved/higher Q values. Further, although capacitor 304 is shown having two sets of intertwined fingers, with each set having three fingers, the techniques variously described herein can be used to form capacitors having sets of intertwined fingers with each set having any number of fingers. For completeness of description, inductor 302 and capacitor 304 may be connected to other passive devices or various active devices to form, for example, an RF or analog circuit. Numerous variations and configurations will be apparent in light of this disclosure.

Example System

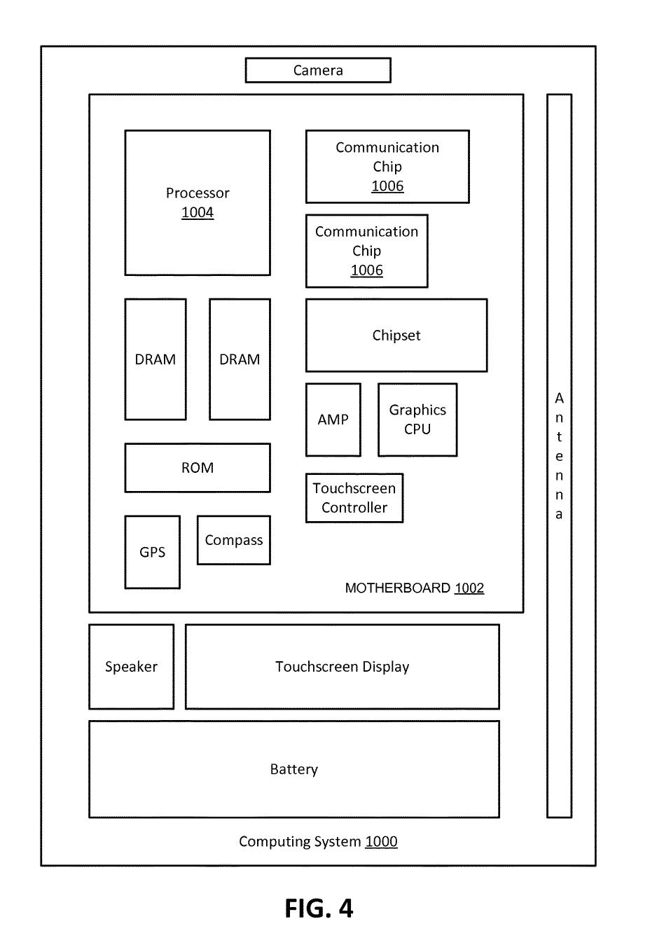

FIG. 4 illustrates a computing system 1000 implemented with integrated circuit structures or devices, such as integrated passive devices (e.g., inductors and/or capacitors), formed using the techniques disclosed herein, in accordance with an example embodiment. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM, STTM, etc.), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3 G, 4 G, 5 G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

The computing system 1000 may include an RF or analog circuit including one or more passive devices formed using the techniques described herein. The RF circuit may be a high frequency circuit (such as a high 3 db cut-off frequency structure) requiring inductors and/or capacitors having high Q values, such as inductors and capacitors as variously described herein.

In various implementations, the computing device 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

Further Example Embodiments

The following examples pertain to further embodiments, from which numerous permutations and configurations will be apparent.

Example 1 is an inductor including: a substrate; and an electrically conductive coil formed on the substrate, the coil having a plurality of connected line portions; wherein the line portions each have a line edge roughness (LER) of 4 nm or less.

Example 2 includes the subject matter of Example 1, wherein the substrate comprises silicon (Si) and/or germanium (Ge).

Example 3 includes the subject matter of any of Examples 1-2, wherein the electrically conductive coil comprises at least one metal material.

Example 4 includes the subject matter of any of Examples 1-3, wherein the line portions each have an LER of 2 nm or less.

Example 5 includes the subject matter of any of Examples 1-4, wherein the maximum distance between any two adjacent and substantially parallel line portions is 30 nm.

Example 6 includes the subject matter of any of Examples 1-5, wherein the maximum distance between any two adjacent and substantially parallel line portions is 10 nm.

Example 7 includes the subject matter of any of Examples 1-6, wherein the line portions each have a thickness of 30 nm or less.

Example 8 includes the subject matter of any of Examples 1-7, wherein the line portions each have a thickness of 10 nm or less.

Example 9 includes the subject matter of any of Examples 1-8, wherein the angle between any two line portions is between 60 and 140 degrees.

Example 10 includes the subject matter of any of Examples 1-9, wherein the angle between any two line portions is within 5 degrees of 90 degrees.

Example 11 includes the subject matter of any of Examples 1-10, wherein a corner between any two connected line portions is sharper than can be achieved if the inductor were formed using 193 nm photolithography.

Example 12 includes the subject matter of any of Examples 1-11, wherein the inductor has a higher Q value than can be achieved if the inductor were formed using 193 nm photolithography.

Example 13 is a radio frequency (RF) or analog circuit including the subject matter of any of Examples 1-12.

Example 14 is a computing system including the subject matter of any of Examples 1-12.

Example 15 is a capacitor including: a substrate; a first set of electrically conductive fingers; and a second set of electrically conductive fingers intertwined with the first set of fingers; wherein the sets of fingers comprise a plurality of connected line portions, the line portions each having a line edge roughness (LER) of 4 nm or less.

Example 16 includes the subject matter of Example 15, wherein the substrate comprises silicon (Si) and/or germanium (Ge).

Example 17 includes the subject matter of any of Examples 15-16, wherein the sets of fingers comprise at least one metal material.

Example 18 includes the subject matter of any of Examples 15-17, wherein the line portions each have an LER of 2 nm or less.

Example 19 includes the subject matter of any of Examples 15-18, wherein the maximum distance between any two adjacent and substantially parallel line portions is 30 nm.

Example 20 includes the subject matter of any of Examples 15-19, wherein the maximum distance between any two adjacent and substantially parallel line portions is 10 nm.

Example 21 includes the subject matter of any of Examples 15-20, wherein the line portions each have a thickness of 30 nm or less.

Example 22 includes the subject matter of any of Examples 15-21, wherein the line portions each have a thickness of 10 nm or less.

Example 23 includes the subject matter of any of Examples 15-22, wherein the angle between any two line portions is between 60 and 140 degrees.

Example 24 includes the subject matter of any of Examples 15-23, wherein the angle between any two line portions is within 5 degrees of 90 degrees.

Example 25 includes the subject matter of any of Examples 15-24, wherein a corner between any two connected line portions is sharper than can be achieved if the capacitor were formed using 193 nm photolithography.

Example 26 includes the subject matter of any of Examples 15-25, wherein the capacitor has a higher Q value than can be achieved if the capacitor were formed using 193 nm photolithography.

Example 27 is a radio frequency (RF) or analog circuit including the subject matter of any of Examples 15-26.

Example 28 is a computing system including the subject matter of any of Examples 15-26.

Example 29 is a method of forming a passive device, the method including: providing a substrate; forming an electrically conductive layer on the substrate; forming a resist on the electrically conductive layer; patterning the resist using a lithography process that requires one or no masks and is capable of achieving resist features having sub-30 nm critical dimensions; and etching the pattern into the electrically conductive layer.

Example 30 includes the subject matter of Example 29, wherein the lithography process is electron-beam lithography.

Example 31 includes the subject matter of Example 30, wherein the electron-beam lithography includes multiple beams.

Example 32 includes the subject matter of any of Examples 29-31, wherein the lithography process is maskless.

Example 33 includes the subject matter of Example 29, wherein the lithography process is extreme ultraviolet lithography (EUVL).

Example 34 includes the subject matter of Example 29, wherein the lithography process is nanoimprint lithography.

Example 35 includes the subject matter of any of Examples 29-34, wherein the passive device is an inductor.

Example 36 includes the subject matter of any of Examples 29-34, wherein the passive device is a capacitor.

Example 37 includes the subject matter of any of Examples 29-36, wherein the electrically conductive layer comprises at least one metal.

Example 38 includes the subject matter of any of Examples 29-37, wherein the lithography process can achieve line edge roughness (LER) of 4 m or less for the resist features.

Example 39 includes the subject matter of any of Examples 29-38, wherein the lithography process can achieve line edge roughness (LER) of 2 nm or less for the resist features.

Example 40 includes the subject matter of any of Examples 29-39, wherein the lithography process is capable of achieving resist features having sub-10 nm critical dimensions.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

1. An inductor comprising:
a substrate; and
an electrically conductive coil formed on the substrate, the coil having a plurality of connected line portions;
wherein the line portions each have a line edge roughness (LER) of 4 nm or less.

2. The inductor of claim 1, wherein the electrically conductive coil comprises at least one metal material.

3. The inductor of claim 1, wherein the line portions each have an LER of 2 nm or less.

4. The inductor of claim 1, wherein the maximum distance between any two adjacent and substantially parallel line portions is 30 nm.

5. The inductor of claim 1, wherein the angle between any two line portions is within 5 degrees of 90 degrees.

6. The inductor of claim 1, wherein the inductor has a higher Q value than can be achieved if the inductor were formed using 193 nm photolithography.

7. A radio frequency (RF) or analog circuit comprising the inductor of claim 1.

8. A computing system comprising the inductor of claim 1.

9. A capacitor comprising:
a substrate;
a first set of electrically conductive fingers; and
a second set of electrically conductive fingers intertwined with the first set of fingers;
wherein the sets of fingers comprise a plurality of connected line portions, the line portions each having a line edge roughness (LER) of 4 nm or less.

10. The capacitor of claim 9, wherein the sets of fingers comprise at least one metal material.

11. The capacitor of claim 9, wherein the line portions each have an LER of 2 nm or less.

12. The capacitor of claim 9, wherein the maximum distance between any two adjacent and substantially parallel line portions is 30 nm.

13. The capacitor of claim 9, wherein the angle between any two line portions is within 5 degrees of 90 degrees.

14. The capacitor of claim 9, wherein the capacitor has a higher Q value than can be achieved if the capacitor were formed using 193 nm photolithography.

15. A radio frequency (RF) or analog circuit comprising the capacitor of claim 9.

16. A computing system comprising the capacitor of claim 9.

17. A method of forming a passive device, the method comprising:
providing a substrate;
forming an electrically conductive layer on the substrate;
forming a resist on the electrically conductive layer;
patterning the resist using a lithography process that requires one or no masks and is
capable of achieving resist features having sub-30 nm critical dimensions; and
etching the pattern into the electrically conductive layer.

18. The method of claim 17, wherein the lithography process is electron-beam lithography.

19. The method of claim 18, wherein the electron-beam lithography includes multiple beams.

20. The method of claim 17, wherein the lithography process is maskless.

21. The method of claim 17, wherein the lithography process is extreme ultraviolet lithography (EUVL).

22. The method of claim 17, wherein the lithography process is nanoimprint lithography.

23. The method of claim 17, wherein the passive device is an inductor.

24. The method of claim 17, wherein the passive device is a capacitor.

25. The method of any claim 17, wherein the lithography process can achieve line edge roughness (LER) of 4 nm or less for the resist features.
